(19) United States
(12) Patent Application Publication
(10) Pub. No.: US 2024/0304608 A1
(43) Pub. Date: Sep. 12, 2024

(54) NATURAL SPHERICAL SURFACE LED MODULE

(71) Applicant: DESIGNLED TECHNOLOGY CORP., El Monte, CA (US)

(72) Inventors: Ligang ZHAO, El Monte, CA (US); Lei LIANG, El Monte, CA (US); Chengwei MA, El Monte, CA (US); Guangming SONG, El Monte, CA (US); Jie ZHOU, El Monte, CA (US); Youhe ZHANG, El Monte, CA (US)

(21) Appl. No.: 18/179,886

(22) Filed: Mar. 7, 2023

(51) Int. Cl. H01L 25/13; H01L 33/48

(52) U.S. Cl. CPC H01L 25/13; H01L 33/486

(57) ABSTRACT

The patent application discloses an LED module. The LED module is removably connected to a source of constant current. The LED module may comprise a substrate and an electrical circuit. The substrate may have a parallel top and bottom side, a curved side connected to both ends of the top and bottom sides to form a quadrilateral shape. The electrical circuit is mounted and molded on the substrate. The electrical circuit may comprise an LED.

### TECHNICAL FIELD

This invention concerns a display system, in particular, this invention concerns a spherical LED display system.

### BACKGROUND

Light emitting diodes (“LEDs”) are ubiquitous in electronics. They are used in digital displays, lighting systems, computers and televisions, cellular telephones and a variety of other devices. Developments in LED technology have led to methods and systems for the generation of white light using one or more LEDs. Developments in LED technology have led to LEDs that generate more photons and thus lighter than previously. The culmination of these two technological developments is that LEDs are being used to supplement or replace many conventional lighting sources, e.g. incandescent, fluorescent or halogen bulbs, much as the transistor replaced the vacuum tube in computers.

LED display is popular due to its energy-conservation and technical advantage of long service life. More and more LED display is used widely in current technology, however, current spherical or near spherical LED display screen is not as smooth as a perfect globe. Therefore, there is a need to have a smooth spherical LED display screen for aesthetic reasons.

### SUMMARY

In one aspect, one embodiment discloses an LED module removably connected to a source of constant current. The LED module may comprise a substrate and an electrical circuit. The substrate may have a parallel top and bottom side, a curved side connected to both ends of the top and bottom sides to form a quadrilateral shape. The electrical circuit may be mounted and molded on the substrate. The electrical circuit may comprise an LED.

Optionally in any aspect, the substrate comprises a heat sink for dissipating heat.

Optionally in any aspect, the module comprises a support to the substrate.

Optionally in any aspect, the support includes at least one mounting region at an edge.

Optionally in any aspect, the mounting region comprises at least one magnet.

Optionally in any aspect, the module includes an insulating cover.

Optionally in any aspect, the insulating cover is molded onto the module.

Optionally in any aspect, the support is attached to a skeleton by the magnet.

Optionally in any aspect, the support further comprises aluminum.

In further another aspect, one embodiment discloses LED module. The LED module comprises a substrate and a support. The substrate may comprise at least one LED mounted onto a surface of the substrate. The substrate may be connected to the support. Various sizes of LED modules and the substrate are flexible and curved to form a spherical shape.

Optionally in any aspect, the substrate has a parallel top and bottom side, a curved side connected to both ends of the top and bottom sides to form a quadrilateral shape.

Optionally in any aspect, the substrate includes a heat sink for dissipating heat.

Optionally in any aspect, the support includes at least one mounting region at an edge for mounting the module.

Optionally in any aspect, the mounting region comprises at least one magnet.

Optionally in any aspect, the module may include an insulating cover.

Optionally in any aspect, the insulating cover is molded onto the module.

Optionally in any aspect, the module may include a heat sink.

In still further another aspect, one embodiment discloses a spherical LED display system comprising a plurality of removable LED modules connected to a support. Each removable LED module may comprise a curved substrate and an electrical circuit. The electrical circuit may be mounted and molded on the curved substrate. The electrical circuit comprises an LED mounted on the substrate.

Optionally in any aspect, the length (L) of the parallel top or bottom side of the quadrilateral shape may be defined as the following formula: L=π*D*COS[(90/N)*(n−1)*π/180]/M. In the formula, D=diameter of a globe the module is assembling for. N=number of latitude dividing the globe (the larger number of the latitude, the better or smoother of the globe); n=the nth of the latitude; M=number of the LED modules.

Optionally in any aspect, the substrate comprises a heat sink for dissipating heat.

Optionally in any aspect, the support includes at least one mounting region at an edge for mounting the module.

Optionally in any aspect, the mounting region comprises at least one magnet.

Optionally in any aspect, the module includes an insulating cover.

Optionally in any aspect, the insulating cover is molded onto the module.

Optionally in any aspect, the module includes a heat sink.

Optionally in any aspect, the module further comprises a support to the substrate.

Optionally in any aspect, the support further comprises aluminum.

### BRIEF DESCRIPTION OF THE DRAWINGS

In order to illustrate the technical solutions more clearly in the embodiments of the present disclosure or the exemplary techniques, the drawings to be used in the embodiments or the description of the exemplary embodiments will be briefly described below. Obviously, the drawings in the following description are only certain embodiments of the present disclosure, and other drawings may be obtained according to the structures shown in the drawings without any creative work for those skilled in the art.

FIG. 1 is a front view of a LED system exemplifying an embodiment of the invention;

FIG. 2 is an enlarged view of LED module connected to a skeleton with some of the skeleton exposed according to one exemplary embodiment.

FIG. 3 is a perspective side view of a LED with a substrate according to one exemplary embodiment;

FIG. 4 is a perspective front view of a LED with a substrate according to one exemplary embodiment; and

FIG. 5 is front view of an LED or a substrate having a curved shape according to one exemplary embodiment

The implementation, functional features and advantages of the present disclosure will be further described with reference to the accompanying drawings.

### DETAILED EMBODIMENTS

### Definitions

The invention is not limited to the particular methodology, protocols, and reagents described herein because they may vary. Further, the terminology used herein is for the purpose of describing particular embodiments only and is not intended to limit the scope of the present invention. As used herein and in the appended claims, the singular forms “a,” “an,” and “the” include plural reference unless the context clearly dictates otherwise.

Unless defined otherwise, all technical and scientific terms and any acronyms used herein have the same meanings as commonly understood by one of ordinary skill in the art in the field of the invention. Although any methods and materials similar or equivalent to those described herein can be used in the practice of the present invention, the preferred methods, devices, and materials are described herein. The technical means, creative features, objectives, and effects of the patent application may be easy to understand, the following embodiments will further illustrate the patent application. However, the following embodiments are only the preferred embodiments of the utility patent application, not all of them. Based on the examples in the implementation manners, other examples obtained by those skilled in the art without creative work shall fall within the protection scope of the present invention. The experimental methods in the following examples are conventional methods unless otherwise specified. The materials and reagents used in the following examples can be obtained from commercial sources unless otherwise specified.

Accordingly, the present invention may take the form of an entirely hardware embodiment, such as, a computer, a PC, a laptop, or an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product embodied in any tangible medium of expression having computer-usable program code embodied in the medium.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction performance system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireless, wireline, optical fiber cable, RF, etc.

Computer program code for carrying out operations of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Exemplary embodiments of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions.

These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

### The Embodiments

Embodiments of the present invention are directed to LED modules for a spherical display device, and software for implementing the LED modules.

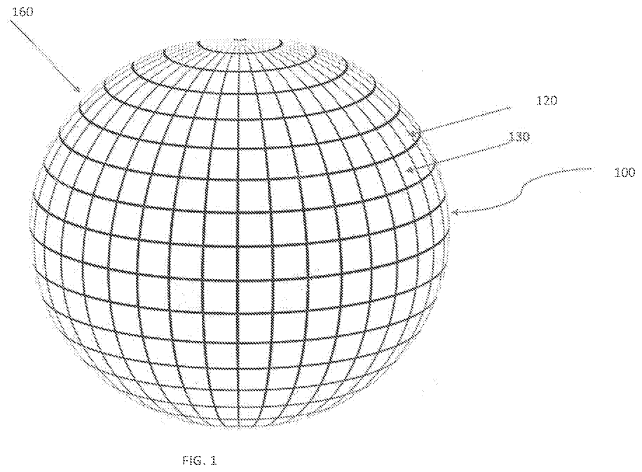

Referring first to FIG. 1, a spherical LED display system 100 may comprise a plurality of removable LED modules 160. The spherical LED display system 100 may comprise a plurality of latitude lines 120 and longitude lines 130. The latitudes 120 are horizontal lines that measure distance north or south of the equator. Longitudes 130 are vertical lines that measure east or west of a meridian (not shown).

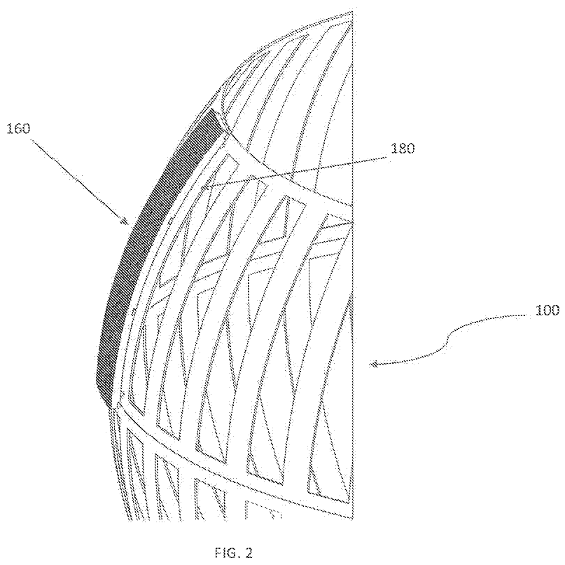

As shown in FIG. 2, the removable LED module 160 may be connected to a skeleton 180. The skeleton 180 may be formed a globe structure so that the removable LED module 160 could be removably attached to the skeleton 180. The skeleton 180 may be made of iron, for example.

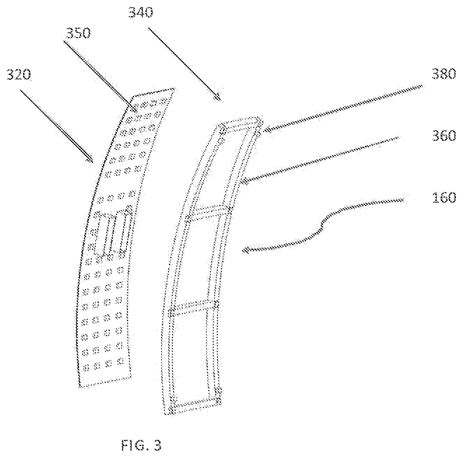

Referring to FIG. 3, each removable LED module 160 may comprise a curved substrate 320 and a support 340. The support 340 may stabilize the substrate 320. The support 340 may have at least one mounting region 360 at an edge of the support 340. The mounting region 360 may comprises at least one magnet 380. The curved substrate 320 may be glued to the support by various kinds of adhesives, such as an epoxide resin AB glues.

For an epoxide resin AB glue for high ambient conditions, comprise A and B two components, A and B two components carry out proportioning according to following component and parts by weight thereof:
1) component A may be:
E44 epoxy resin 60 parts
F51 epoxy resin 25 parts
MHR-070 glycolylurea epoxide resin 10 parts
JEW-0113 aliphatic epoxy resin 10 parts
Polyurethane modified epoxy resin 10 parts
Silicon powder 25 parts;
2) B component may be:
650 Versamids 50 parts
4,4′-diaminodiphenylsulfone (DDS) 2 parts
2-ethyl 4-methylimidazole 5 parts
Mphenylenediamine 20 parts
Silicon powder 20 parts
Thermal silica 3 parts.

During preparation, A and B two kinds of components are made respectively, independent packaging, wherein:
1) being prepared as follows of component A:

Bisphenol A type epoxy resin, bisphenol F epoxy resin, glycolylurea epoxide resin and aliphatic epoxy resin are added respectively in three mouthfuls of beakers, be heated to 115-125 DEG C., not stopping stirring makes it be heated evenly, add epoxy toughening agent again, make it be dissolved into completely in beaker after the liquid of uniformity and stop heating, be cooled to room temperature and add again after mineral filler mixes and namely obtain component A;
2) being prepared as follows of B component:

First by 2-ethyl 4-methylimidazole, 4,4′-diaminodiphenylsulfone (DDS)s and mphenylenediamine; Add in beaker, heating and melting at 115-125 DEG C., the complete post liquefaction of thing to be mixed can stop heating. Cooled liquid, and Versamid mixing, then add mineral filler and then can obtain B component.

After AB two kinds of components are made, independently wire up, during use by component A and B component according to parts by weight proportioning for 100:30-80 chooses, and to implement according to following step operation:
1) surface treatment: the surface treatment of material is undertaken by the requirement of product design or process stipulation. Glue surfaces answers clean, dry, nothing oil:
2) join glue: prepare in proportion, glue is placed in cleaning, drying, without oily container, mixes to solid colour;
3) be coated with: be uniformly coated on two splicing faces with glue cutter or scraper plate, its glue spread is just extruded a tree lace with the splicing bonding surface after combination and is advisable;
4) combine: superimposed as early as possible after gluing, apply the contact pressure of 0.01-0.05 MPa, and be combined into place by drawing;
5) solidify: under the contact pressure of 0.01-0.05 MPa, select 145-155 degree Celsius to be incubated 2 hours, and can solidify completely with after stove cooling;
6) processing or test: gluing member, after solidifying completely, can proceed to next procedure processing or make a service test.

The support 340, which may be made of aluminum, may be attached to the skeleton 180 (shown in FIG. 2) by the magnet 380. The substrate 320 may comprise a heat sink 350 for dissipating heat.

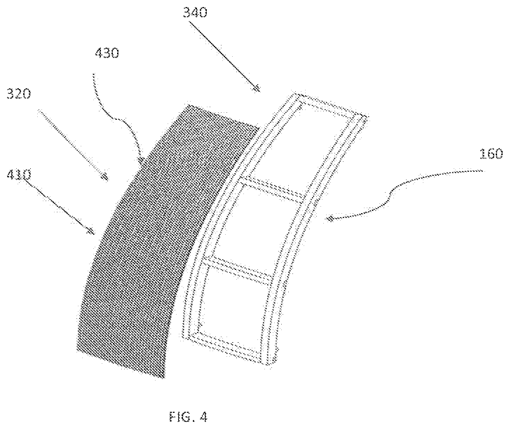

As shown in FIG. 4, the LED module 160 may comprise an electrical circuit 410 mounted and molded on the substrate 320. The electrical circuit may comprise an LED.

The LED module 160 may include an insulating cover 430. The insulating cover 430 may be molded onto the LED module 160.

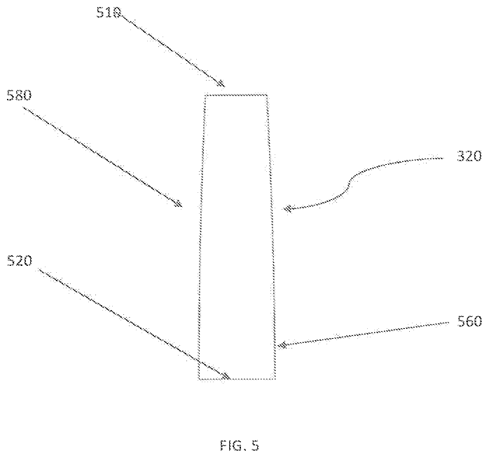

As shown in FIG. 5, the substrate 320 may be a curved substrate, which have a parallel top 510 and bottom 520. Curved sides 560 and 580 may connect to both ends of the top 510 and bottom side 520 to form a quadrilateral shape. The curved sides 560 and 580 may not be straight lines. The length of top 510 may be shorter than that of the bottom 520.

The length (L) of the parallel top 510 or bottom 520 of the quadrilateral shape is defined by the following formula: L=π*D*COS[(90/N)*(n−1)*π/180]/M and picture below:
D=diameter of a globe the module is assembling for
N=number of latitude dividing the globe (the larger number of the latitude, the better or smoother of the globe)
n=the nth of the latitude
M=number of the LED modules.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

The above shows and describes the basic principles, main features and advantages of the patent application. Those skilled in the industry should understand that the present patent application is not limited by the above-mentioned embodiments. The above-mentioned embodiments and the description are only preferred examples of the present patent application and are not intended to limit the present patent application, without departing from the present utility patent application. Under the premise of spirit and scope, the present utility patent application will have various changes and improvements, and these changes and improvements fall within the scope of the claimed utility patent application. The scope of protection claimed by the utility patent application is defined by the appended claims and their equivalents.

We claim:

1. An LED module removably connected to a source of constant current, comprising:
a substrate having a parallel top and bottom side, a curved side connected to both ends of the top and bottom sides to form a quadrilateral shape; and
an electrical circuit mounted and molded on the substrate, said electrical circuit comprising an LED.

2. The module according to claim 1, wherein the length (L) of the parallel top or bottom side of the quadrilateral shape is defined as the following formula: L=π*D*COS[(90/N)*(n−1)*π/180]/M
D=diameter of a globe the module is assembling for
N=number of latitude dividing the globe (the larger number of the latitude, the better or smoother of the globe)
n=the nth of the latitude
M=number of the LED modules

3. The module according to claim 1 further comprises a support to the substrate.

4. The module according to claim 3, wherein the support includes at least one mounting region at an edge of the support.

5. The module according to claim 4, wherein the mounting region comprises at least one magnet.

6. The module according to claim 1, wherein the module includes an insulating cover.

7. The module according to claim 6, wherein the insulating cover is molded onto the LED module.

8. The module according to claim 5, wherein the support is attached to a skeleton by the magnet.

9. The module according to claim 4, wherein the support comprises aluminum.

10. Light emitting diode (LED) module, comprising
a substrate;
at least one LED mounted onto a surface of the substrate; and
a support, wherein the substrate is connected to the support, wherein various sizes of LED and the substrate are flexible and curved to form a spherical shape.

11. The module according to claim 10, wherein the substrate has a parallel top and bottom side, a curved side connected to both ends of the top and bottom sides to form a quadrilateral shape.

12. The module according to claim 10, wherein the substrate has a smaller length on the top than the bottom sides.

13. The module according to claim 10, wherein the support includes at least one mounting region at an edge for mounting the module.

14. The module according to claim 13, wherein the mounting region comprises at least one magnet.

15. The module according to claim 10, wherein the module includes an insulating cover.

16. The module according to claim 10, wherein the insulating cover is molded onto the LED.

17. The module according to claim 14, wherein the support is attached to a skeleton by the magnet.

18. A spherical LED display system comprising a plurality of removable LED modules connected to a support, each removable LED module comprising:
a curved substrate; and
an electrical circuit mounted and molded on the curved substrate, said electrical circuit comprises an LED mounted on the substrate.

19. The spherical LED display system of claim 18, wherein the curved substrate has a parallel top and bottom side, a curved side connected to both ends of the top and bottom sides to form a quadrilateral shape.

20. The spherical LED display system of claim 18, wherein the length (L) of the parallel top or bottom side of the quadrilateral shape is defined as the following formula:
$$L = π * D * COS [ ( 90 / N ) * ( n - 1 ) * π / 180 ] / M$$
D=diameter of the globe
N=number of latitude dividing the globe (the larger number of the latitude, the better of the spherical globe)
n=the nth of the latitude
M=number of the LED modules
